(19) United States
(12) Patent Application Publication
(10) Pub. No.: US 2010/0290503 A1
(43) Pub. Date: Nov. 18, 2010

(54) Ultra-High Temperature Distributed Wireless Sensors

(75) Inventors: Raymond Charles Rumpf, JR., Christiansburg, VA (US); John Moore Coggin, Blacksburg, VA (US); Stephen Hamilton Poland, Blacksburg, VA (US)

Correspondence Address: THE H.T. THAN LAW GROUP, WATERFRONT CENTER SUITE 560, 1010 WISCONSIN AVENUE NW, WASHINGTON, DC, 20007, US

(73) Assignee: Prime Photonics, LC, Blacksburg, VA (US)

(21) Appl. No.: 12/779,688

(22) Filed: May 13, 2010

Related U.S. Application Data
(60) Provisional application No. 61/216,095, filed on May 13, 2009.

(51) Int. Cl. G01K 7/00; G01L 1/00; G01R 29/08

(52) U.S. Cl. 374/163; 73/774; 374/E07.001

(57) ABSTRACT

A passive wireless sensor is disclosed. The sensor has at least a measurand sensitive member and an electromagnetically resonant member positioned proximate to each other. The resonant member comprises a preselected resonance frequency, such that it scatters at least a portion of an interrogating signal as a scattered signal proximate to its resonance frequency, and the measurand sensitive member alters the scattered signal as a function of the measurand to change the shape of the scattered signal. The reactive field of the sensor is kept within the sensor to minimize environment interference and to maximize its signal strength. Almost bond-free packaging mitigates problems with delamination or internal stresses due to differing coefficients of thermal expansion.

### CROSS-REFERENCE TO RELATED PATENT APPLICATION

The present patent application claims the benefit under Title 35, United States Code, §119(e) to U.S. provisional patent application Ser. No. 61/216,095 filed on 13 May 2009. Provisional application Ser. No. 61/216,095 is incorporated by reference herein in its entirety.

### FIELD OF THE INVENTION

The present invention is related to a sensor to accurately measure various physical properties, such as temperature or pressure, in harsh or inhospitable environments. More specifically, the present invention is directed to a remote, passive sensor that primarily changes the shape of its resonance frequency curve in response to the measured property(ies).

### BACKGROUND OF THE INVENTION

In ultra-high temperature environment, such as internal combustion engines, turbine engines, and coal gasification power plants where temperature reaches well above 1000° C., there exists a need to remotely monitor various measurands or parameters like temperature, pressure, strain, chemical species concentration, etc. In coal-gasifier power plants, electricity from coal gasification is cleaner, more efficient, and is likely to contribute significantly to the country's energy need. Coal gasification power plants are more efficient and the carbon dioxide produced therein can be captured more readily than in coal-burning power plants. Sustained, efficient operation of a gasification plant is challenging and requires that the plant operates at optimal temperature to crack the volatile hydrocarbons and to promote the thermo-chemical reactions that generate the syngas.

Temperature sensors such as thermocouples, optical pyrometers, optical sensors and acoustic sensors have been used but with limited success. Wireless or remote sensors that have built-in electrical components have also been used. In one example, U.S. Published Patent Application No. 2009/0188396 to Hofmann et al. discloses an active wireless temperature sensor for monitoring food temperature. The sensor includes circuitry and a battery to provide power to the built-in wireless transmitter. In another example, U.S. Pat. No. 5,942,991 to Gaudreau et al. shows a plurality of wireless sensors having a discrete resonant LC circuit that emits electromagnetic return signals representative of a state of the resonance characteristic in response to an electromagnetic excitation signal. “A Passive Wireless Temperature Sensor For Harsh Environment Applications” to Wang et al., Sensors 2008, 8, pages 7982-7995, describes an RF powered LC circuit sensor which measures temperature based on the shift in frequency. “Wireless Ceramic Sensors Operating In High Temperature Environments” to Birdsell et al., presented in the 40^{th} AIAA/ASME/SAE/ASEE Joint Propulsion Conference, Fort Lauderdale, Fla., July 2004, describes a similar wireless LC sensor.

These prior art sensors require either electrical components formed thereon, such as inductors and capacitors, or a power source, or both. Built-in electrical components require complex manufacturing and are susceptible to damage and errors caused by thermal expansion or contraction, and therefore have limited operating temperature ranges. Additionally, the prior art sensors utilize the changes in the temperature dependent dielectric constant to measure temperature, which would cause a shift in the resonance frequency.

Hence, there remains a need to provide wireless sensors for operation in hostile environments that don't require a power source or built-in electrical components.

### SUMMARY OF THE INVENTION

The present invention is directed to a passive sensor that can scatter an interrogating signal at or proximate to its resonance frequency. As used herein, scatter, scatters, scattered, scattering or similar words include reflected signals as well as transmitted signals. The shape of the scattered resonance signal can be sensitive to several parameters to be measured, including but not limited to the temperature of the object to be measured. In one embodiment, the shape (Q) of the scattered signal at the resonance frequency becomes flatter as the temperature increases. Hence, the Q factor of the scattered signal is directly related to the temperature to be measured.

The inventive passive sensor is preferably free of power sources and free of any electrical components or equivalents thereof. In one embodiment, the inventive sensor preferably comprises a temperature sensitive material that is substantially homogeneous or uniform. The material may have a conductivity that is sensitive to temperature, i.e., its conductivity experiences a loss relative to increasing temperature, a dielectric constant that changes with temperature, or other material properties that change with temperature. In a more preferred embodiment, the electromagnetic loss is magnified or otherwise increased by one or more scattering surfaces provided in the sensor, in order to increase the change in shape of the scattered signal in response to a measurand, e.g., temperature, pressure, etc. The scattering surfaces preferably contain one or more gratings or cutouts. The gratings form the scattering surfaces, and hence the sensor has a selective frequency response. The gratings on one scattering surface may comprise a number of different shapes and configurations. The gratings also establish the resonance and allow the interrogating signals to enter and the scattered signals to exit the sensor after being magnified. Preferably, the temperature sensitive material and the scattering surfaces are encased in a housing that protects the sensor and allows the interrogating and scattered signals to pass through.

In a preferred embodiment, the structure of the sensor is designed so that the reactive or evanescent field of the sensor is substantially contained within the physical dimensions of the sensor, so that the environmental debris, such as dust and soot, would not significantly affect the response of the sensor. One way to accomplish this is to position one scattering surface on each side of the temperature sensitive material.

In one embodiment, the inventive passive sensor includes a ceramic sheet, whose conductivity is dependent on temperature, sandwiched between two metal slot arrays. This stack is then hermetically sealed and encapsulated in a single crystal sapphire package in order to be protected from extremely high temperature and corrosive environment. Advantageously, the components of the inventive sensor are preferably not laminated to each other, so that the sensor is better able to tolerate thermal expansion and contraction.

In another aspect of the invention, an electromagnetic (preferably a RF signal with a sufficient bandwidth) source is used to interrogate the plurality of passive sensors which filter and scatter a portion of incident beam. Each passive sensor is designed to have a unique resonance frequency, so that its scattered signal can be identified, and the measured parameter(s) can be processed. Alternatively, another way of multiplexing the inventive passive sensors is to include a unique RFID (radio-frequency identification) tag to each sensor, so that the scattered signal from the RFID tags can identify the individual sensor, and all sensors can scatter signals at any frequencies including overlapping frequencies. For example, a plurality of sensors could be multiplexed by make each have multiple resonances and distinguishing them like distinguishing bar codes. Frequencies that are different from the resonant frequency would pass through the device, would scatter as if the frequency selective member was not resonant, or would scatter weakly. At resonance, the energy is confined and concentrated in the conductive ceramic layers, which dampens the resonance. The response of the sensor may be characterized by the quality factor (Q) of the resonance. The Q factor is not significantly affected by thermal expansion and contraction or by channel attenuation. Changes in Q-factor are linked to the measured physical parameter and can be calibrated.

### BRIEF DESCRIPTION OF THE DRAWINGS

In the accompanying drawings, which form a part of the specification and are to be read in conjunction therewith and in which like reference numerals are used to indicate like parts in the various views:

FIG. 1 is a schematic view of a wireless, remote sensor system in accordance with the present invention;

FIG. 2 a graphical illustration of the operation of an inventive sensor;

FIG. 3A is an exploded view of an embodiment of the inventive sensor; FIG. 3B is a perspective view of the sensor of FIG. 3A when assembled;

FIG. 4 is a schematic view of another embodiment of the inventive sensor;

FIG. 5 is simulation of the sensor of FIG. 4 to determine the resonance response as a function of temperature and to determine the relationship between the Q factor, the conductivity (a) and temperature (T);

FIG. 6 is an exploded view of another embodiment of the present invention;

FIG. 7 shows two perspective views of alternative frequency selective members;

FIG. 8 shows three inventive sensors of different sizes to demonstrate the relationship between the dimensions of the sensors, grating spacing and selected frequency of the sensor; and

FIGS. 9(a)-9(c) are exploded views of alternative inventive sensors positioned on top of the assembled inventive sensors.

### DETAILED DESCRIPTION OF THE PREFERRED EMBODIMENTS

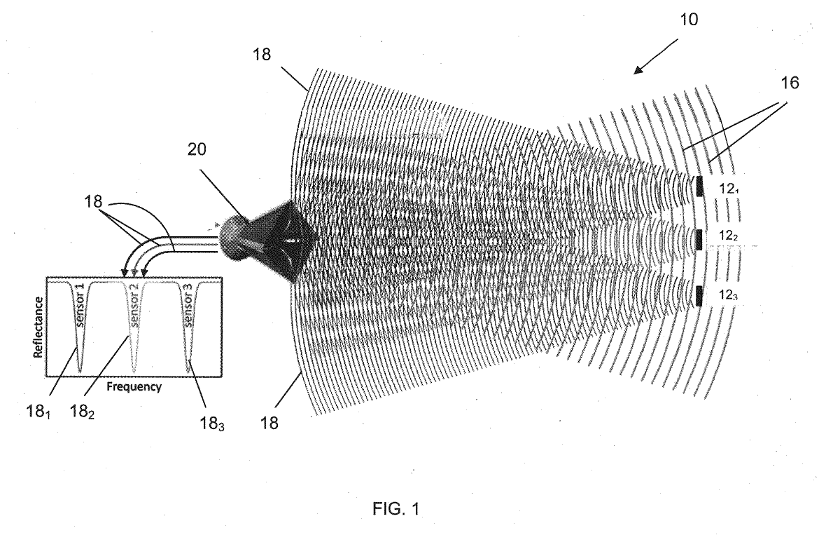

In one exemplary embodiment, the present invention comprises a wireless, remote sensor system 10 for measuring temperatures at multiple locations, particularly in high-temperature or inhospitable environments described above, in which a broadband interrogating source, preferably but not limited to radio frequency range (RF), interrogates an array of passive wireless sensors 12ᵢ distributed throughout a chamber such as a coal gasification chamber, as illustrated in FIG. 1. Three sensors 12₁, 12₂, and 12₃ are shown; however, the invention is not limited to any number of sensors. Each wireless, remote temperature sensor 12 comprises a temperature sensitive element and a frequency selective element, preferably a metamaterial, and the frequency selective element is selected to respond or scatter electromagnetic energy at or near its resonance frequency. As used herein, metamaterial includes man-made or engineered materials that generally gain their properties from their structure rather than their composition. Sensors 12 filter and scatter a portion of the incident energy in a manner that can be detected by a receiver and processed by the interrogator, even in the presence of electromagnetic interference (EMI) and multipath interference. Sensors 12 can be multiplexed either by designing them to operate at slightly different frequencies or by using RF barcode techniques. Multiple other transduction mechanisms are possible and other physical parameters such as pressure and strain can be addressed by the present invention.

The principle of operation of wireless sensor system 10 is illustrated in FIG. 1. A broadband source 14 illuminates an array of passive sensors 12, which filter and scatter some of the incident energy 16. The scattered signals 18 travel back to the source where they are detected and processed by a receiver 20. Sensors 12 are designed so that physical parameters, such as temperature, pressure, or strain, modify the spectral response in a manner that can be used to distinguish the sensors and make accurate measurements. By constructing the temperature sensitive member in sensors 12 from high temperature materials, e.g., ceramics such as YSZ or silicon carbide (SiC) among others, and encapsulating it in sapphire, wireless sensors can be made to operate at extremely high temperatures and resist corrosion. YSZ describes yttria-stabilized zirconia, which is a zirconium-oxide based ceramic, in which the particular crystal structure of zirconium oxide is made stable at high temperature by an addition of yttrium oxide. These oxides are commonly called “zirconia” (ZrO₂) and “yttria” (Y₂O₃). Other suitable temperature sensitive materials include, but are not limited to, barium titanate (BaTiO₃), lanthanum doped calcium manganese oxide (CaMnO) and lanthanum chromite (LaCrO₃). Suitable temperature sensitive materials should have a high dielectric conductivity or loss tangent (tan δ) at very high frequency. More particularly, suitable temperature sensitive materials should have (i) high migration losses (including DC conductivity losses, ion jump losses and dipole relaxation losses), (ii) high ion vibration and deformation losses and/or (iii) electron polarization losses. The present invention is not limited to any particular temperature sensitive materials. Additionally, suitable temperature sensitive materials can include non-ceramic materials.

Furthermore, the frequency selective materials of sensor 12 are designed to scatter at or proximate to their resonance frequencies, which can be at any range in the electromagnetic spectrum, i.e., inside the RF range or outside of the RF range. Hence, the present invention is also not limited to the RF range. Additionally, the frequency selective materials can have multiple resonance frequencies so that sensor 12 can be responsive to multiple interrogating frequencies.

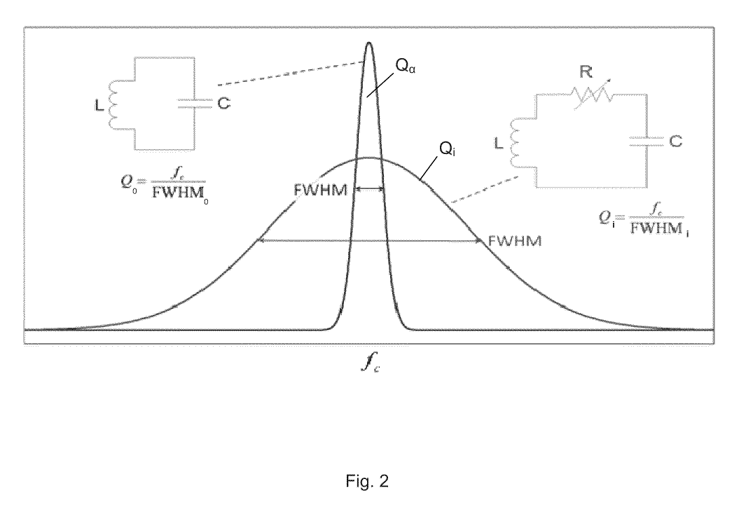

While many transduction mechanisms are possible, a preferred technique is using the quality factor (Q) of a resonator as illustrated in FIG. 2. According to one aspect of the present invention, sensors 12 have resonance frequencies in the RF range, and partially scatter the incident energy at or near their resonance frequencies and allowing the remaining incident energy to pass through. The Q factor of a resonance can be defined as the center frequency divided by its full width at half maximum (FWHM).

$$Q = \frac{{f}_{c}}{F W H M} \qquad ( 1 )$$

While sensors 12 of the present invention do not contain any electrical components, such as inductors, capacitors or resistors, an illustration of the Q factor can arise in a simple LC circuit, which will produce a resonance from which an initial Qₒ can be defined. When resistance is incorporated into the circuit, the resonance is weakened and broadened which lowers Qᵢ. As shown, the center frequency (f_{c}) in the Q factor changes very little, i.e., the resonance response does not necessarily shift. A property like temperature can be measured through changes in the Q factor if the resistive element changes with temperature. Resonance will be produced using subwavelength metamaterials to interact with the RF waves and produce an analogous resonance. Resistive high temperature materials like YSZ or SiC are incorporated to dampen the resonance in response to temperature. Empirical data can be obtained by experiments to create calibration curves relating the changes in the Q factor to changes in temperature for the temperature sensitive materials at various resonance wavelengths.

The approach of using the Q factor is advantageous in that it has certain immunity to mechanical deformation of sensor 12 and to channel attenuation, which can distort measurements. Q is also immune to channel attenuation, because the value of Q is independent of the amplitude of the resonance.

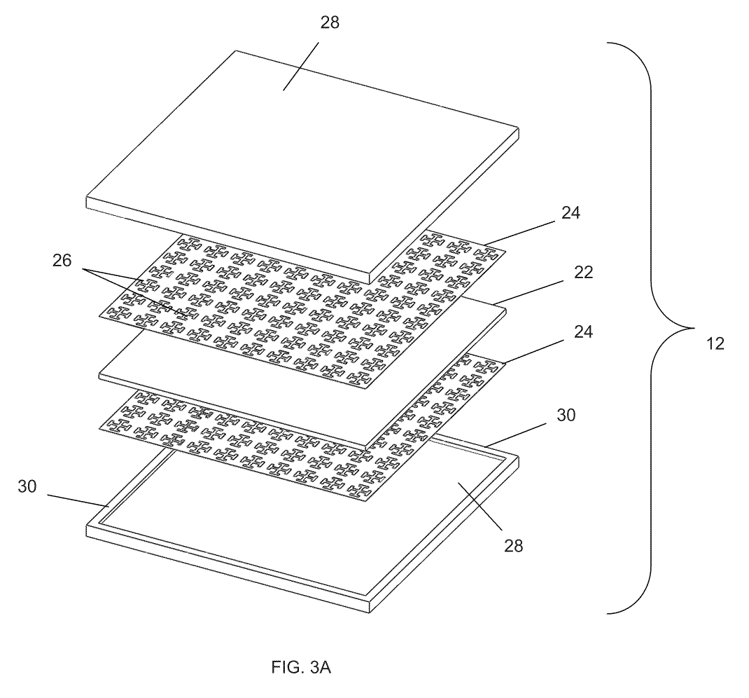

FIGS. 3A and 3B illustrate one preferred embodiment of inventive sensor 12. As shown, sensor 12 comprises at its center temperature sensitive member 22, which can be a ceramic material such as YSZ or SiC, that has a conductivity, σ(T), which is the inverse of resistivity discussed above with respect to FIG. 2 and changes with respect to temperature. As temperature changes the resistivity or conductivity of member 22 varies to change the shape of the scattered resonance signal, as shown in FIG. 2.

To scatter interrogating signal 16 at a preselected frequency, sensor 12 has at least one frequency selective member 24 positioned on one side of temperature sensitive member 22, and preferably on both sides of member 22. Preferably, each frequency selective 24 is made from a metal slot array, which can be a metal sheet, such as copper, tungsten, stainless steel, etc., with a plurality of gratings 26 formed thereon. An analogy can be made to the natural frequency of a simple mechanical system. Gratings 26 alter the springiness (k) of the metal sheet and help determine the natural frequency or resonance of frequency selective member 24. The natural frequency of a simple mechanical system can be expressed as

$$f = \frac{1}{2 π} \sqrt{\frac{k}{M}} \qquad ( 2 )$$

Where k is the spring constant of the system and M is the mass of the system. Hence, frequency selective member 24 is an electromagnetically resonant member.

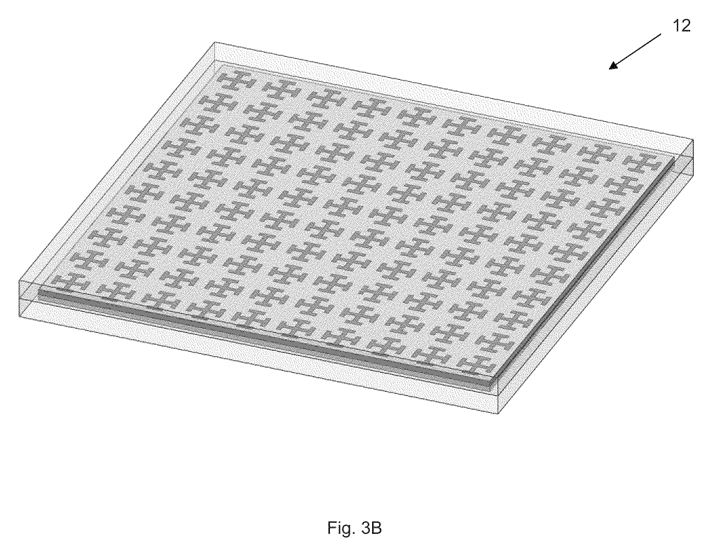

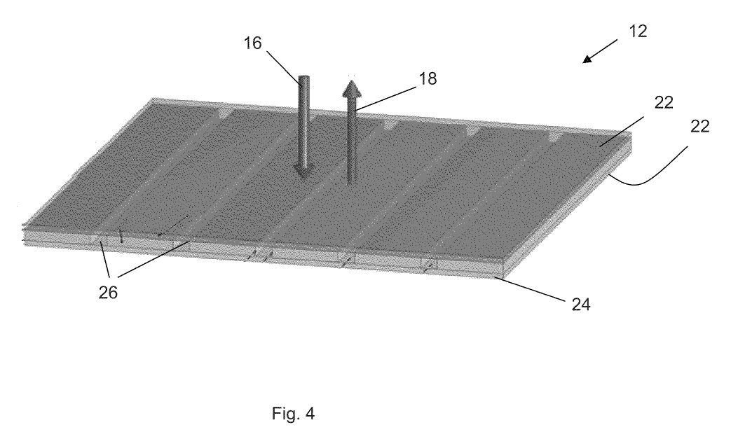

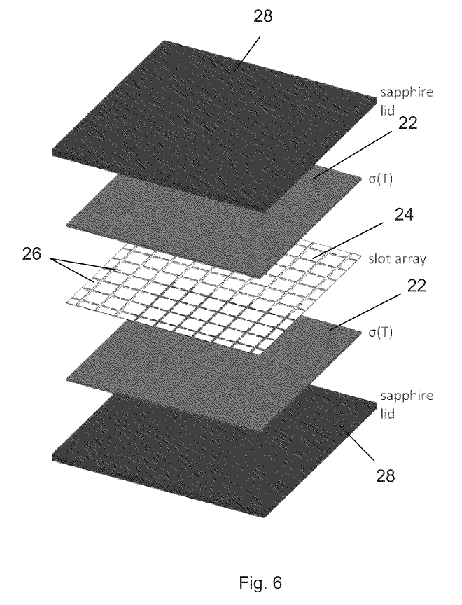

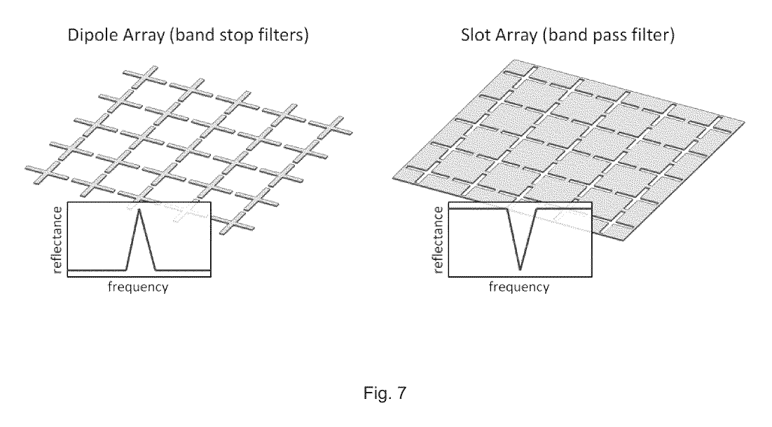

Gratings 26 can have any shape, spacing or dimensions as long as they perform their intended function. Gratings 26 can have the shape of a cross, a starburst, a Jerusalem cross (as shown in FIG. 3), slits (shown in FIG. 4), slot array (shown in FIG. 6) or dipole (shown in FIG. 7), among others such as circular, oval, regular and irregular polygonal shape, etc. Additionally, multiple shapes of gratings can appear on a single frequency selective member 24. The present invention is not limited to any particular grating shape or combination of grating shapes.

Interrogating signal 16 and scattered signals 18 generally would not penetrate the metal sheet, except through gratings 26. Between the two frequency selective members 24, scattered signal 18 travels through the temperature sensitive material 22 and bounces between members 24. Each time the scattered signal travels through the temperature sensitive material 22, the conductivity loss due to the resistivity of material 22 is amplified, thereby amplifying the scattered resonance signal.

Sensor 12 preferably also has housing member 28 which is made from a material that is resistance to heat, temperature expansion/contraction and corrosion, among other things. Preferably, housing 28 comprises two halves, as shown. Suitable materials for housing 28 include, but are not limited to, sapphire, alumina, etc. Each half has ledge or lip 30, which are sized and dimensioned to provide space to receive elements 22 and 24. The halves are hermetically sealed together at ledge 30 to encase elements 22 and 24 therewithin, as illustrated in FIG. 3B. Advantageously, elements 22, 24 and 28 are not laminated together to minimize any effects from the differences in thermal expansion or contraction of these elements.

In accordance with another aspect of the present invention, sensor 12 as illustrated in FIGS. 3A and 3B is designed to maintain the sensor's evanescent wave, also known as the reactive field, within housing 28 and more preferably within scattering members 24. Evanescent wave is a near field standing wave that has its intensity decreases with distance from the location or boundary where the wave is formed. Electromagnetic interferences (EMI), dust or soot can negatively affect the operation of sensor 12, if the evanescent wave of sensor 12 extends outside sensor 12. The embodiment of FIGS. 3A and 3B is one embodiment where sensor 12's evanescent wave is kept within the sensor. An advantage of this embodiment is that the interference caused by EMI, dust or soot is minimized. Also, since sensor 12 is not connected by wire to the receiver/transmitter, the wire cannot act as antenna to capture EMI signals.

The embodiment of FIGS. 3A and 3B are normally reflective, but are transmissive and absorptive on and near the resonance. Scattering surfaces 24 with gratings 26 are extended over temperature sensitive member 22. At resonance frequency, this structure which is normally reflective outside of resonance becomes transmissive and/or absorptive with significantly higher intensity at the resonance condition. On, or near, the resonance, the reactive or evanescent fields are strong, but decay exponentially outside the scattering surfaces 24. In most applications, it is advantageous to confine this field inside the sensor as much as possible so that fluctuations in the sensors response are only due to fluctuations in the material properties inside the sensor. A large evanescent field outside the sensor can be advantageous when sensing things physically outside the sensor.

Another embodiment of sensor 12 is shown in FIG. 4. In this embodiment, two layers of temperature sensitive members 22 are provided and are positioned on either side of frequency selective member 24 having gratings 26′ thereon. In this embodiment two temperature sensitive members are used to increase the conductivity loss due to the resistivity of member 22, and scattering member 24 is a metamaterial designed with narrow slits/gratings 26 to provide a resonance proximate to the expected from temperature sensitive member 22.

As shown in FIG. 4, frequency selective metamaterials may be used to enhance the Q based transduction process. A ruled metal grating with narrow slits 26 is used as frequency selective member 24 and is placed between two sheets of temperature sensitive member 22 made from YSZ. The metal grating was designed to provide a narrow resonance near 70 GHz anticipating that this frequency will have favorable propagation characteristics and allowing the sensor size to be small. The YSZ films were incorporated to introduce a temperature-dependant resistance to dampen the resonance and alter the Q factor with temperature. The film thickness was optimized so the sensor would cover the full temperature range from 600° C. to 1600° C. with maximum sensitivity. Gratings 26 can also comprise a slot array instead of slits, as shown in FIG. 6. Gratings 26 can also be circular, oval, triangular, regular or irregular polygons, etc. Furthermore, as illustrated in FIG. 7, the slot array acts similar to a band pass filter and the inverse of the slot array, i.e., dipole array, which acts similar to a band stop filter, can also be utilized as gratings 26.

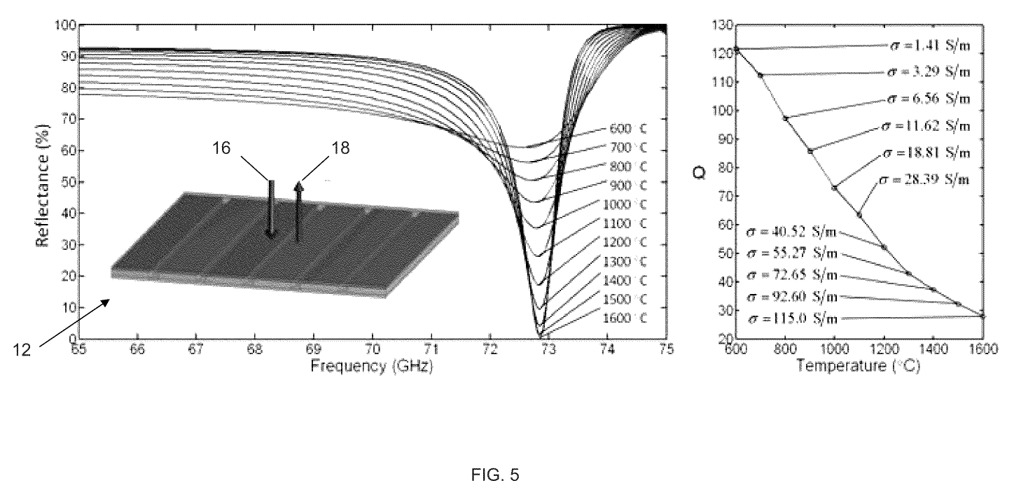

Sensor 12 as shown in FIG. 4 was simulated using a finite-difference frequency-domain technique. Data for the conductivity as a function of temperature at gigahertz frequencies could not be found in the literature and not known in the prior art. Instead, the DC conductivity for the preliminary simulations was used, and the results are summarized in FIG. 5. At 600° C., the scattered energy spectrum showed a strong dip just below 73 GHz. Simulations were then performed for this same sensor at increments of 100° C. As temperature was increased, the conductivity increased, as discussed above. This dampened the resonance and lowered the Q factor. A plot relating the Q factor to the temperature is provided in the rightmost diagram and shows that a strong signal response was obtained from this design. It was observed that a wide range of potential conductivity responses could be accommodated through proper choice of the film thickness of these layers.

Depending on the natural frequency or resonance of sensor 12, the present invention can also operate in higher frequency ranges. In one embodiment, due to advantageous data processing among other reasons wireless sensor system 10 can operate in the terahertz range, which generally ranges from 300 GHz (3×10¹¹ Hz) to 3 THz (3×10¹² Hz). One method of altering the resonance frequency of sensor 12 is to vary gratings 26. Sensor 12 of the present invention may also operate in the microwave, infrared, optical, and x-ray, or virtually any other sub-ranges of the electromagnetic spectrum.

In accordance with another aspect of the present invention, the size and frequency of operation of sensor 12 are controlled by several factors. First, experimental testing can identify any frequency bands that should be avoided or favored due to attenuation from the operating environment, such as hot gases or particulates in the coal gasifier or boiler. However, attenuation of the electromagnetic waves may not be significant at any frequency due to the low concentration of conductive particles in the operational atmosphere. For a chosen frequency f, i.e., the chosen resonant frequency, the free space wavelength λ₀ is calculated as

$${λ}_{0} = \frac{{c}_{0}}{f} , \qquad ( 3 )$$

where c₀ is the speed of light in air. High frequencies correspond to shorter wavelengths so size of the sensor can be reduced by operating at a higher frequency. In general, higher frequencies involve more expensive components and are more vulnerable to channel effects, hence preferably the present invention should operate at as low of a frequency as practicable.

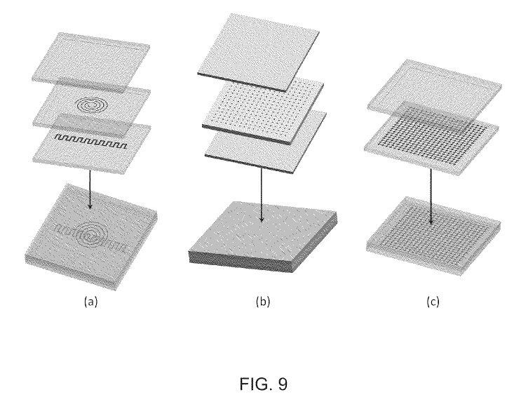

Second, the period of the gratings “a” inside the sensor is approximately half of the free space wavelength or smaller. For the structure depicted in FIG. 9, the element spacing is just under a quarter of this wavelength. The specific answer to this item depends on the physical mechanism on which the sensor is based. Mechanisms can be broadly categorized into resonant and non-resonant modes of operation. Resonant devices are based on the scattering of the electromagnetic wave and require spacing between grating unit cell to be around half the wavelength. Non-resonant structures do not scatter electromagnetic waves, but are instead based on surface currents resonating on the subwavelength scale. Resonant structures are typically larger in size and their resonant frequency is determined more strongly by the spacing and layout of the elements in the array instead of the shape of the elements themselves. Non-resonant structures are typically smaller in size and the resonant frequency is more strongly dependant on the shape of the elements in the array instead of their spacing or layout. Otherwise, both can be made to provide very similar behavior

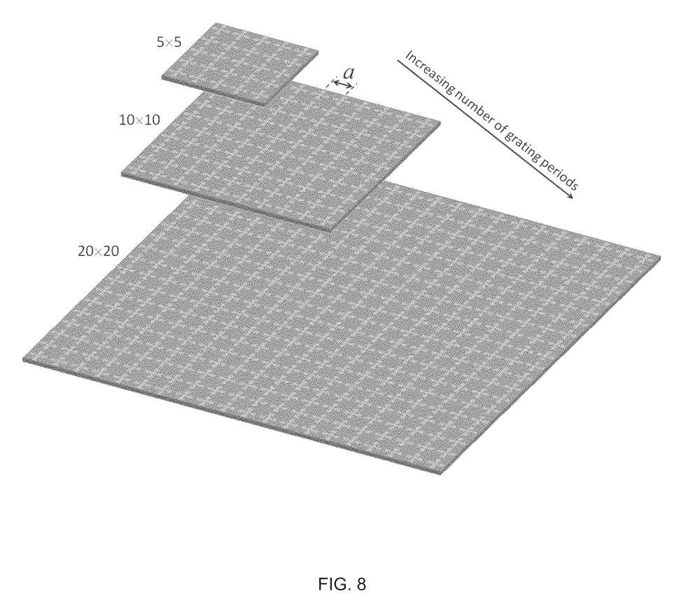

Third, the total physical size of the sensor is the grating period multiplied by the total number of periods. The more periods the sensor incorporates the stronger the electromagnetic response, but the larger the sensor. This is illustrated in FIG. 8. In other words, small sensors can be designed to operate at higher frequencies.

Another degree of freedom in the design of the sensor is the elements themselves. These are the patterns that are repeated across the array. Their geometry controls how strongly electromagnetic waves scatter off of them and their array spacing and layout controls in what directions scattering occurs. These can be explored to produce as strong of an electromagnetic response as possible in as small of a form factor as possible. Slow wave structures couple external waves into slowly propagating surface waves within the sensor. This effectively reduces the wavelength in the array so the element size and spacing can be made much smaller than λ₀/2. One way that slow wave structures can be produced is by operating the array near a resonance condition such as a degenerate band edge.

The elements are usually designed to produce a narrow spectral response. Elements can be the resonant type where a=λ₀/2 or they can be non-resonant where a<<λ₀/2. Narrow resonances arise when the coupling to external waves is weak. This configuration also means that larger grating arrays may be needed to allow for sufficient coupling to occur. A typical design effort seeks to minimize the sensor size relative to the wavelength. From there, frequency can be increased so the sensor is an acceptable size.

In one example, a simulated reflectance from an infinite array of slot elements in a copper sheet, as would be the case if fabricated using standard printed circuit board techniques. In one non-limiting example, with a grating period of 0.697 cm, the structure produces a strong null around 10 GHz where the device is resonant. Smaller slots typically will produce a narrower resonance due to weaker coupling so width of the resonance can be controlled. Shape of the slots can be tailored for the same purpose.

Although the design described above utilizes temperature-induced changes in electromagnetic loss to change the Q factor of a passive sensor, virtually any material response can be exploited. For example, materials that have a dielectric constant sensitive to temperature can be built into resonators to shift the resonance frequency. Sensors can be designed to produce an amplitude response, frequency response, or a polarization response. Of these, a frequency response is anticipated to provide the strongest response and the greatest immunity to noise and other signal distortion mechanisms.

There are many design alternatives that can be considered. Some of these concepts are illustrated in FIGS. 9A-C. FIG. 9A shows a sensor with dual antennae; FIG. 9B shows a sensor with a frequency selective surface; and FIG. 9C shows a sensor with a circuit analog absorber. In the dual antenna configuration, one antenna receives a signal which is then fed through the sensor to the transmitting antenna where the signal is radiated from the sensor. The sensor functions by modifying the received signal while it is in the sensor. The frequency selective surface establishes a resonance which is made sensitive to a measurand like temperature by incorporating materials that alter their electromagnetic properties with temperature. The resonance and its shape can be interrogated from the signal scattered by the sensor. Circuit analog absorbers are highly absorptive in their region of resonance. Geometries resembling more conventional RFID tags or frequency selective metamaterial surfaces are also possible. Of these, circuit analog absorbers may be particularly applicable because they make use of resistive materials to form the elements. If scattering from particles and other surfaces are problematic, form birefringent films made of high temperature dielectrics can be placed over the device to modify its polarization response. This can be used to distinguish the wireless sensor from other background clutter.

According to another aspect of the present invention, the conductivity of metal is also dependent on temperature (σ(T)). It is known that σ(T) decreases when temperature increases. When frequency selective member 24 is made from a metal grating, as described above, member 24 may perform as the electromagnetically resonant member due to gratings 26 and as the temperature sensitive member 22 due to σ(T) of metal. In this embodiment, sensor 12 may be simplified to metal grating acting as both members 22 and 24 being held inside housing 28.

While it is apparent that the illustrative embodiments of the invention disclosed herein fulfill the objectives stated above, it is appreciated that numerous modifications and other embodiments may be devised by those skilled in the art. One such modification is that the sensor could also be based on a shift in resonance frequency due to the dielectric constant changing with some measurand. It could be modified to measure strain, pressure, or chemical substance concentrations by selecting a material for member 22 of sensor 12 that is responsive to strain, pressure or chemical substance, so that the Q factor of sensor 12 is sensitive to these measurand. Modifications also include different shaped elements in the arrays, and placement of elements directly inside the sensing materials. Further, the sensor can be for other applications such as tracking and location where an array of receivers is positioned such that the position of the sensor can be determined. Therefore, it will be understood that the appended claims are intended to cover all such modifications and embodiments, which would come within the spirit and scope of the present invention.

We claim:

1. A wireless sensor comprising:
a measuring member which is sensitive to a measurand and a frequency selective member positioned proximate to each other, wherein the frequency selective member comprises a preselected resonance frequency, such that it scatters at least a portion of an interrogating signal as a scattered signal proximate to its resonance frequency and wherein the measuring member dampens the scattered signal as a function of the measurand to change the quality (Q) factor of the scattered signal, and wherein the wireless sensor is passive.

2. The sensor of claim 1, wherein the measuring member has an electromagnetic loss that varies with temperature.

3. The sensor of claim 1, wherein the measuring member has an electromagnetic loss that varies with strain, pressure or chemical substance.

4. The sensor of claim 2, wherein the measuring member comprises a ceramic material.

5. The sensor of claim 4, wherein the measuring member comprises a material selected form a group consisting of YSZ, SiC, BaTiO₃, La-doped CaMnO and LaCrO₃.

6. The sensor of claim 1, wherein the frequency selective member comprises a metamaterial.

7. The sensor of claim 1, wherein the frequency selective member comprises a metal grating.

8. The sensor of claim 1, wherein the frequency selective member comprises a plurality of gratings.

9. The sensor of claim 1, wherein the frequency selective member comprises a plurality of dipoles.

10. The sensor of claim 8, wherein the gratings are selected from a group consisting of a cross, a Jerusalem cross, a slit, and a slot array.

11. The sensor of claim 1, wherein the resonance frequency is in the radio frequency range.

12. The sensor of claim 1, wherein the resonance frequency is in the terahertz range.

13. The sensor of claim 1, wherein the frequency selective member comprises two members and, wherein said two members are positioned on either side of the measuring member.

14. The sensor of claim 1 further comprising a second measuring member, wherein the measuring member and the second measuring member are positioned on either side of the frequency selective member.

15. The sensor of claim 13, wherein an evanescent wave of the sensor is constrained within the sensor.

16. The sensor of claim 1 further comprising a housing that contains the measuring member and the frequency selective member.

17. The sensor of claim 16, wherein the measuring member and the frequency selective member are unbonded to each other.

18. The sensor of claim 17, wherein the measuring member and the frequency selective member are unbonded to the housing.

19. A wireless sensor comprising a metal grating, wherein the metal is preselected so that its conductivity is measurably sensitive to the range of temperature to be measured, and wherein the metal grating comprises a plurality of gratings such that the metal grating comprises a preselected resonance frequency, such that it scatters at least a portion of an interrogating signal as a scattered signal proximate to its resonance frequency and wherein the metal grating dampens the scattered signal as a function of temperature to change the quality (Q) factor of the scattered signal, and wherein the wireless sensor is passive.

20. The sensor of claim 19, wherein the gratings are selected from a group consisting of a cross, a Jerusalem cross, a slit, and a slot array.
